(19) United States
(12) Patent Application Publication
(10) Pub. No.: US 2005/0067147 A1
(43) Pub. Date: Mar. 31, 2005

(54) Loop thermosyphon for cooling semiconductors during burn-in testing

(76) Inventors: John Gilbert Thayer, Lancaster, PA (US); Donald M. Ernst, Lancaster, PA (US)

Correspondence Address: DUANE MORRIS LLP, P. O. BOX 1003, 305 NORTH FRONT STREET, 5TH FLOOR, HARRISBURG, PA, 17108-1003, US

(21) Appl. No.: 10/929,870

(22) Filed: Aug. 30, 2004

Related U.S. Application Data
(60) Provisional application No. 60/499,483, filed on Sep. 2, 2003.
(60) Provisional application No. 60/502,125, filed on Sep. 11, 2003.

(51) Int. Cl. H05K 7/20

(52) U.S. Cl. 165/80.4; 361/699

(57) ABSTRACT

A burn-in testing cooling system including an evaporator comprising an upright tubular body having an interior surface and a central passageway with a wick disposed on the interior surface of the body that defines the central passageway. A base seals off the central passageway, with an inlet port arranged in flow communication with an upper portion of the central passageway and an outlet port arranged in flow communication with a lower portion of the central passageway. A coolant is disposed within the central passageway. A condenser is arranged in flow communication with the evaporator.

### CROSS-REFERENCE TO RELATED APPLICATIONS

This application claims the benefit of U.S. Provisional Patent Application No. 60/499,483, filed Sep. 2, 2003 and U.S. Provisional Patent Application No. 60/502,125, filed Sep. 11, 2003.

### FIELD OF THE INVENTION

The present invention generally relates to thermal management systems for semiconductor devices and, more particularly, to systems for cooling such semiconductor devices during burn-in testing.

### BACKGROUND OF THE INVENTION

In the conventional manufacture of semiconductor devices, semiconductor wafers are first produced in batches. Each semiconductor wafer can contain many individual electronic devices or electronic circuits, which are known as dies. Each die is electrically tested by connecting it to special purpose test equipment. Probes, which are connected to the test equipment, are brought into contact with the die to be tested. This generally occurs at a prober station, which conventionally includes a platform arranged for supporting the wafer. It is important to test each individual circuit chip die while it is still attached in a wafer, and to also test the individual integrated circuit devices once they have been packaged for their intended use. In many testing applications, the tests must be performed at elevated temperatures which, if not regulated, could cause damage to the chip during testing. Accordingly, automated test systems are commonly outfitted with temperature control systems which can control the temperature of a semiconductor wafer or packaged integrated circuit under test.

For example, and referring to FIGS. 1 and 2, a semiconductor device test system A often includes a temperature-controlled semiconductor package support platform B that is mounted on a prober stage C of prober station D. A top surface E of the device support platform B supports a semiconductor device F and incorporates conventional vacuum line openings and grooves G facilitating secure holding of semiconductor device F in position on top surface E of device support platform B. A system controller and heater power source H are provided to control the temperature of device support platform B. A cooling system I is provided to help regulate the temperature of device support platform B. A user interface is provided in the form of a touch-screen display J where, for example, a desired temperature for the top of support platform B can be input. Temperature controlled systems for testing semiconductor devices during burn-in are well known, as disclosed in the following patents which are hereby incorporated herein by reference: U.S. Pat. Nos. 4,037,830, 4,213,698, RE31053, 4,551,192, 4,609,037, 4,784,213, 5,001,423, 5,084,671, 5,382,311, 5,383,971, 5,435,379, 5,458,687, 5,460,684, 5,474,877, 5,478,609, 5,534,073, 5,588,827, 5,610,529, 5,663,653, 5,721,090, 5,730,803, 5,738,165, 5,762,714, 5,820,723, 5,830,808, 5,885,353, 5,904,776, 5,904,779, 5,958,140, 6,032,724, 6,037,793, 6,073,681, 6,245,202, 6,313,649, 6,394,797, 6,471,913, 6,583,638, and 6,771,086.

In many cases such support platforms are required to be able to both heat and cool the device. Many types of temperature-controlled support platforms are known and are widely available. Cooling is very often provided by a heat sink that is cooled by a recirculating fluid, or in other designs by passing a fluid through the support platform without recirculating it. The fluid can be a liquid or a gas, usually air in the latter case. The liquid or air can be chilled for greater cooling effect in passing through the support platform, and can be recirculated for greater efficiency. A support platform cooled by means of a fluid chilled to a temperature below ambient temperature enables device probing at temperatures below ambient. In general, conventional heat-sink designs often incorporate simple cooling channels cross-drilled and capped in the support platform.

None of the foregoing systems and methods have been found to be completely satisfactory.

### SUMMARY OF THE INVENTION

The present invention provides a cooling system for a semiconductor device including an evaporator comprising an upright tubular body having an interior surface and a central passageway with a wick disposed on the interior surface of the body that defines the central passageway. A base seals off the central passageway, with an inlet port arranged in flow communication with an upper portion of the central passageway and an outlet port arranged in flow communication with a lower portion of the central passageway. A coolant is disposed within the central passageway. A condenser is arranged in flow communication with the evaporator.

In another embodiment of the invention, a cooling system for a plurality of semiconductor devices is provided including a plurality of evaporators. Each evaporator includes an upright tubular body having an interior surface and a central passageway with a wick disposed on the interior surface of the body that defines the central passageway. A base seals off each of the central passageways, and also includes an outlet port arranged in flow communication with an upper portion of each of the central passageways and an inlet port arranged in flow communication with a lower portion of each of the central passageways. A coolant is disposed within each of the central passageways. A condenser is arranged in flow communication with each of the evaporators.

In yet another embodiment of the invention, a cooling system for a plurality of semiconductor devices is provided including a plurality of evaporators. Each evaporator includes an upright tubular body having an interior surface and a central passageway with a wick disposed on the interior surface of the body that defines the central passageway. A base seals off each of the central passageways, and also includes an outlet port arranged in flow communication with (i) an upper portion of each of the central passageways and a common outlet conduit, and (ii) an inlet port arranged in flow communication with a lower portion of each of the central passageways and a common inlet conduit. A coolant is disposed within each of the central passageways. A condenser is arranged in flow communication with each of the evaporators through the common outlet conduit and the common inlet conduit.

### BRIEF DESCRIPTION OF THE DRAWINGS

These and other features and advantages of the present invention will be more fully disclosed in, or rendered obvious by, the following detailed description of the preferred embodiment of the invention, which is to be considered together with the accompanying drawings wherein like numbers refer to like parts and further wherein:

FIG. 1 is a front elevational view of a temperature-controlled semiconductor device testing system of the type contemplated for use with the present invention;

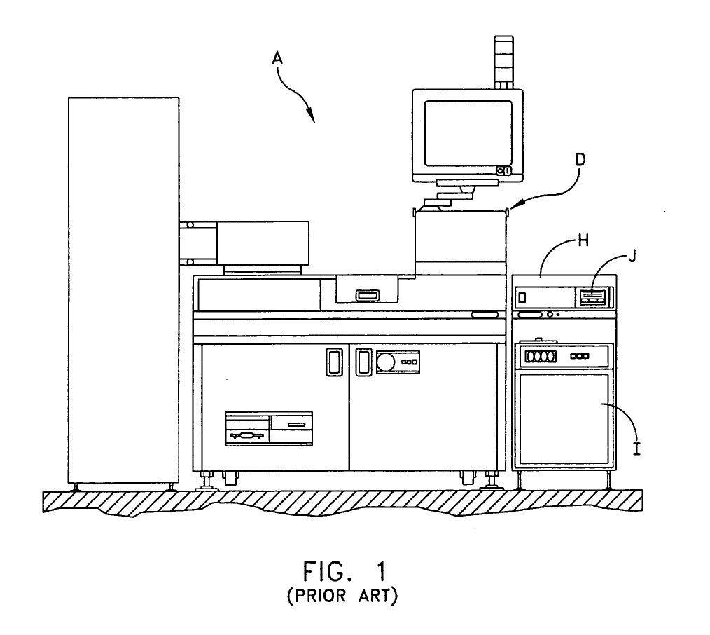

FIG. 2 is an exploded perspective view of an evaporator formed in accordance with the present invention positioned above a semiconductor chip to be cooled atop a support platform of a temperature-controlled semiconductor device testing system;

FIG. 3 is a side elevational view of a loop thermosyphon formed in accordance with one embodiment of the invention;

FIG. 4 is a perspective view of an evaporator formed in accordance with the present invention;

FIG. 5 is a cross-sectional view of the evaporator shown in FIG. 4, as taken along line 5-5 in FIG. 4;

FIG. 6 is a perspective view of an array of evaporators having a common condenser formed in accordance with an alternative embodiment of the present invention;

FIG. 7 is a perspective view of a typical electronics cabinet housing a plurality of arrays of evaporators having a plurality of common condensers formed in accordance with another alternative embodiment of the present invention; and

FIG. 8 is a perspective view of an array of evaporators arranged in flow communication with a common condenser through common conduits formed in accordance with a further embodiment of the present invention.

### DETAILED DESCRIPTION OF THE PREFERRED EMBODIMENT

This description of preferred embodiments is intended to be read in connection with the accompanying drawings, which are to be considered part of the entire written description of this invention. The drawing figures are not necessarily to scale and certain features of the invention may be shown exaggerated in scale or in somewhat schematic form in the interest of clarity and conciseness. In the description, relative terms such as “horizontal,” “vertical,” “up,” “down,” “top” and “bottom” as well as derivatives thereof (e.g., “horizontally,” “downwardly,” “upwardly,” etc.) should be construed to refer to the orientation as then described or as shown in the drawing figure under discussion. These relative terms are for convenience of description and normally are not intended to require a particular orientation. Terms including “inwardly” versus “outwardly,” “longitudinal” versus “lateral” and the like are to be interpreted relative to one another or relative to an axis of elongation, or an axis or center of rotation, as appropriate. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. The term “operatively connected” is such an attachment, coupling or connection that allows the pertinent structures to operate as intended by virtue of that relationship. In the claims, means-plus-function clauses are intended to cover the structures described, suggested, or rendered obvious by the written description or drawings for performing the recited function, including not only structural equivalents but also equivalent structures.

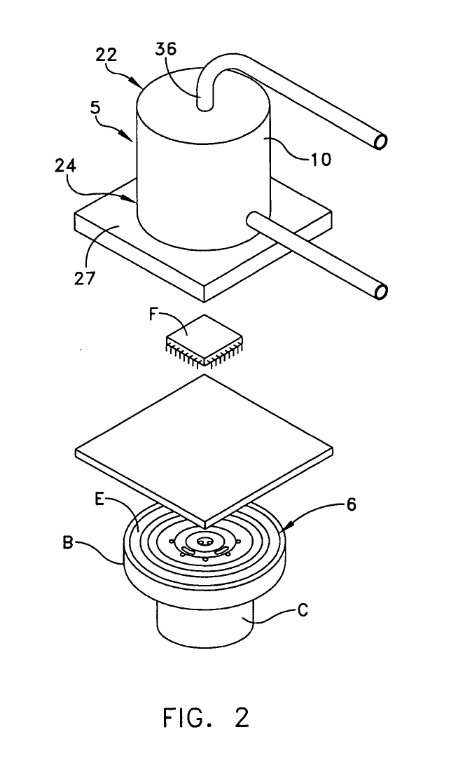

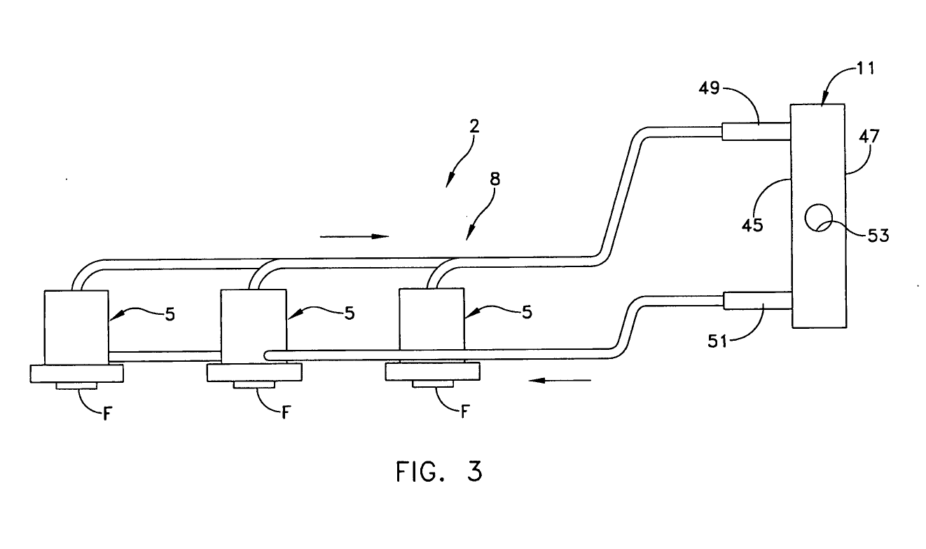

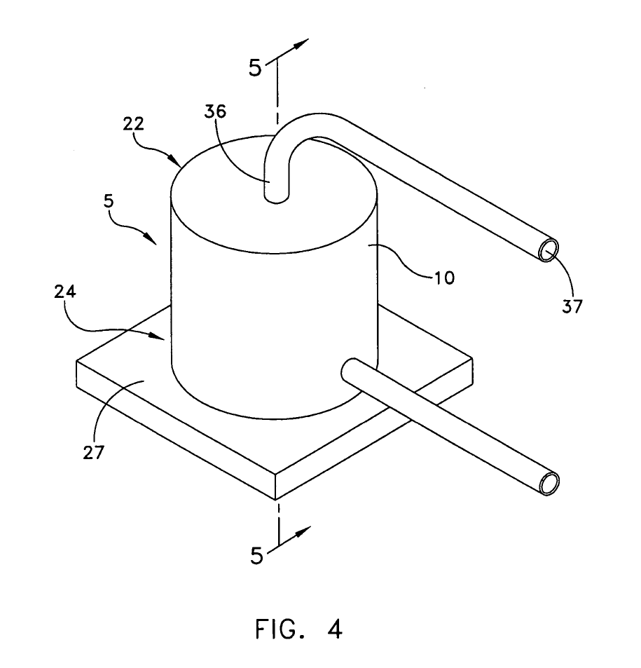

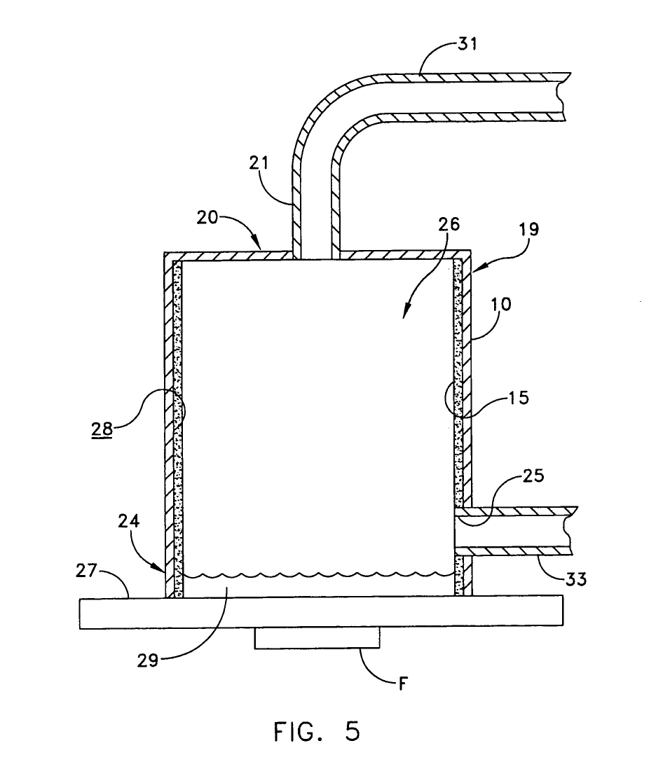

Referring to FIGS. 2-5, a loop thermosyphon system 2 for use in cooling one or more semiconductor devices F during burn-in testing includes one or more evaporators 5, a conduit network 8, and one or more condensers 11 (FIG. 3). More particularly, each evaporator 5 comprises a vessel 10 and a wick 15 (FIGS. 4 and 5). Vessel 10 includes a first end 19, an outlet port 21, a second end 24, an inlet port 25, and a central passageway 26 that is defined by interior surface 28 of vessel 10. Vessel 10 also includes a thermal interface base 27 that is fixedly and hermetically attached to second end 24. A relatively long blind cylinder or tube that is formed from a thermally conductive material, e.g., copper or its alloys, monel, or the like, is often preferred for vessel 10. Of course, other shapes of vessel 10 may be used with equal effect. Central passageway 26 defines a vapor space within vessel 10. Vessel 10 is often about 10 mm in diameter and about 12 mm in height.

Wick 15 is disposed upon interior surface 28 of vessel 10, and may comprise adjacent layers of screening or a sintered powder structure with interstices between the particles of powder. Of course, capillary wick 15 may also other wicking structures, such as, grooves, screen, cables, and felt. In one embodiment, wick 15 may comprise sintered copper powder, sintered aluminum-silicon-carbide (AlSiC) or copper-silicon-carbide (CuSiC) having an average thickness of about 0.1 mm to 1.0 mm. A coolant fluid 29 may comprise any of the well known two-phase vaporizable liquids, e.g., water alcohol, freon, etc.

Conduit network 8 includes an outlet conduit 31 and an inlet conduit 33, both of which often comprise an elongate hollow tubing having a central passageway 37. Conduit network 8 is often formed from stainless steel, copper or its alloys, or the like highly thermally conductive material.

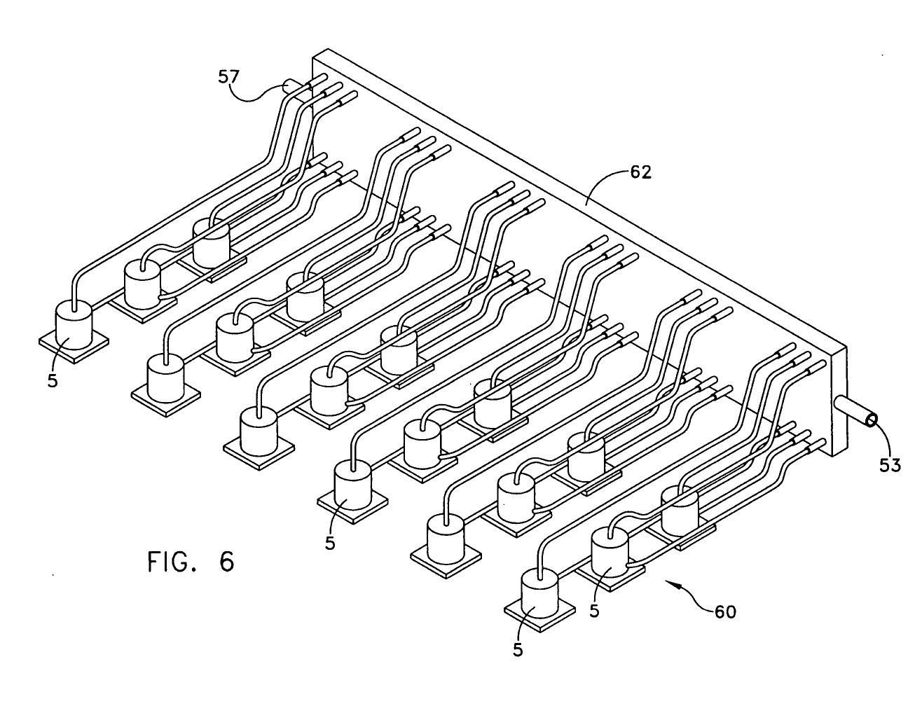

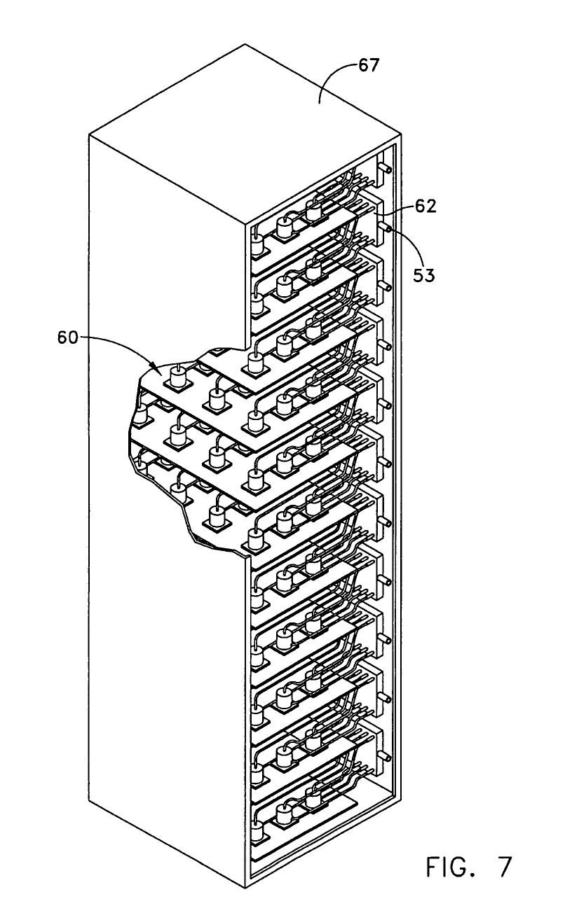

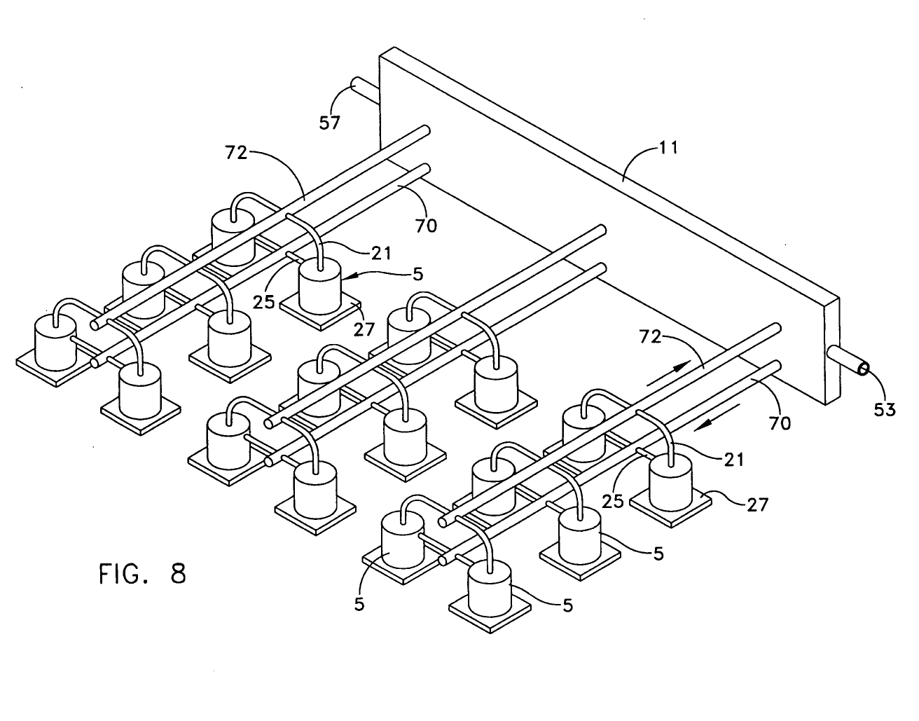

Referring to FIGS. 3, and 6-8, each condenser 11 is formed from a conductive metal, such as copper, aluminum, or steel, and comprises a front wall 45, a rear wall 47, an inlet duct 49, and an outlet duct 51. Each condenser 11 is associated with one or more evaporators 5, with inlet duct 49 arranged in flow communication with at least one evaporator 5, via outlet port 21, and outlet duct 51 arranged in flow communication with at least one evaporator 5, via inlet port 25. Front wall 45 and rear wall 47 include interior confronting surfaces that may include a variety of known surface features (e.g., posts, mesh, grooves, irregularly shaped protrusions, baffles, and wick materials) that are adapted for aiding in the dispersal of thermal energy from coolant fluid 29 to front wall 45 and rear wall 47 as it passes between them. Alternatively, condenser may be a liquid cooled, condenser that is chilled by a flowing liquid or gas, e.g., chilled water or air, entering port 53 from a pumped source (not shown) and exiting condenser 11 via port 57 (FIG. 6).

Each condenser 11 acts as a heat exchanger transferring heat contained in a mixture of vaporous working fluid and liquid working fluid (not shown) to the ambient surroundings, via an external heat sink, e.g., conventional heat exchangers having the capability to facilitate transfer of thermal energy, and that are often heat transfer devices, such as a fin stack, cold plate or secondary heat exchanger of the type well known in the art.

Referring to FIGS. 6-8, a plurality of semiconductor chips F may be cooled simultaneously with an array of evaporators 60 where each evaporator 5 is arranged in flow communication with a common condenser 62. A plurality of arrays 60 may be stacked with in a cabinet 67 for ease of use with a variety of electronics systems. An alternative embodiment, provides a common inlet conduit 70 and common outlet conduit 72 to which evaporators 5 are interconnected in flow communication such that each outlet port 21 is arranged in flow communication with common outlet conduit 72 and, each inlet port 25 is arranged in flow communication with common inlet conduit 70.

In operation, loop thermosyphon system 2 may be used to cool one or more semiconductor devices F in the following manner. A plurality of semiconductor chips F to be cooled (FIGS. 6-8) are thermally coupled to thermal interface base 27. As thermal energy is transferred from the each semiconductor chip F to evaporator 5, coolant fluid 29 which saturates wick 15 within evaporator 5 begins to evaporate (i.e., boil). As coolant fluid 29 boils, the pressure within evaporator 5 increases, which in turn forces a mixture of vaporous coolant fluid to flow through outlet port 21 toward condenser 11. Liquid coolant fluid 29 is condensed within condenser 11 and returns to evaporator 5 via inlet port 25.

It is to be understood that the present invention is by no means limited only to the particular constructions herein disclosed and shown in the drawings, but also comprises any modifications or equivalents within the scope of the claims.

1. A cooling system for a semiconductor device comprising, in combination:
an evaporator comprising an upright tubular body having an interior surface and a central passageway with a wick disposed on said interior surface of said body that defines said central passageway;
a base sealing off said central passageway;
an inlet port arranged in flow communication with an upper portion of said central passageway and an outlet port arranged in flow communication with a lower portion of said central passageway;
a coolant disposed within said central passageway; and
a condenser arranged in flow communication with said evaporator.

2. A cooling system according to claim 1 wherein said evaporator includes a wick selected from the group consisting of adjacent layers of screening, a sintered powder structure with interstices between the particles of powder, grooves, screen, cables, and felt.

3. A cooling system according to claim 1 wherein said wick comprises at least one of sintered copper powder, sintered aluminum-silicon-carbide (AlSiC) and copper-silicon-carbide (CuSiC) having an average thickness of about 0.1 mm to 1.0 mm.

4. A cooling system according to claim 1 comprising a conduit network including an outlet conduit and an inlet conduit each comprising elongate hollow tubing having a central passageway wherein said outlet conduit is arranged in flow communication between said outlet port and said condenser and said inlet conduit is arranged in flow communication between said inlet port and said condenser.

5. A cooling system according to claim 1 wherein said condenser is formed from a conductive metal and comprises a front wall, a rear wall, an inlet duct, and an outlet duct such that at least one condenser is thermally engaged with at lest one evaporator such that said inlet duct is arranged in flow communication with said outlet port of said evaporator and said outlet duct is arranged in flow communication with said inlet port.

6. A cooling system according to claim 5 wherein said front wall and said rear wall include interior confronting surfaces that include surface features selected from the group consisting of posts, mesh, grooves, irregularly shaped protrusions, and baffles that disperse thermal energy from a coolant fluid to said front wall and said rear wall.

7. A cooling system for a plurality of semiconductor devices comprising, in combination:
a plurality of evaporators each comprising an upright tubular body having an interior surface and a central passageway with a wick disposed on said interior surface of said body that defines said central passageway;
a base sealing off each of said central passageways;
an outlet port arranged in flow communication with an upper portion of each of said central passageways and an inlet port arranged in flow communication with a lower portion of each of said central passageways;
a coolant disposed within each of said central passageway; and
a condenser arranged in flow communication with each of said evaporators.

8. A cooling system according to claim 7 wherein each of said evaporators includes a wick selected from the group consisting of adjacent layers of screening, a sintered powder structure with interstices between the particles of powder, grooves, screen, cables, and felt.

9. A cooling system according to claim 7 wherein said wick comprises at least one of sintered copper powder, sintered aluminum-silicon-carbide (AlSiC) and copper-silicon-carbide (CuSiC) having an average thickness of about 0.1 mm to 1.0 mm.

10. A cooling system according to claim 7 comprising a conduit network including an outlet conduit and an inlet conduit each comprising elongate hollow tubing having a central passageway wherein said outlet conduit is arranged in flow communication between said outlet port and said condenser and said inlet conduit is arranged in flow communication between said inlet port and said condenser.

11. A cooling system according to claim 7 wherein said condenser is formed from a conductive metal and comprises a front wall, a rear wall, an inlet duct, and an outlet duct such that at least one condenser is thermally engaged with at lest one evaporator such that said inlet duct is arranged in flow communication with said outlet port of each of said evaporators and said outlet duct is arranged in flow communication with said inlet port.

12. A cooling system according to claim 5 wherein said front wall and said rear wall include interior confronting surfaces that include surface features selected from the group consisting of posts, mesh, grooves, irregularly shaped protrusions, and baffles that disperse thermal energy from a coolant fluid to said front wall and said rear wall.

13. A cooling system for a plurality of semiconductor devices comprising, in combination:
a plurality of evaporators each comprising an upright tubular body having an interior surface and a central passageway with a wick disposed on said interior surface of said body that defines said central passageway;
a base sealing off each of said central passageways;
an outlet port arranged in flow communication with (i) an upper portion of each of said central passageways and a common outlet conduit, and (ii) an inlet port arranged in flow communication with a lower portion of each of said central passageways and a common inlet conduit;
a coolant disposed within each of said central passageways; and
a condenser arranged in flow communication with each of said evaporators through said common outlet conduit and said common inlet conduit.

14. A cooling system according to claim 13 wherein each of said evaporators includes a wick selected from the group consisting of adjacent layers of screening, a sintered powder structure with interstices between the particles of powder, grooves, screen, cables, and felt.

15. A cooling system according to claim 13 wherein said wick comprises at least one of sintered copper powder, sintered aluminum-silicon-carbide (AlSiC) and copper-silicon-carbide (CuSiC) having an average thickness of about 0.1 mm to 1.0 mm.

16. A cooling system according to claim 13 comprising a conduit network including an outlet conduit and an inlet conduit each comprising elongate hollow tubing having a central passageway wherein said outlet conduit is arranged in flow communication between said outlet port and said condenser and said inlet conduit is arranged in flow communication between said inlet port and said condenser.

17. A cooling system according to claim 13 wherein said condenser is formed from a conductive metal and comprises a front wall, a rear wall, an inlet duct, and an outlet duct such that at least one condenser is thermally engaged with at lest one evaporator such that said inlet duct is arranged in flow communication with said outlet port of each of said evaporators and said outlet duct is arranged in flow communication with said inlet port.

18. A cooling system according to claim 17 wherein said front wall and said rear wall include interior confronting surfaces that include surface features selected from the group consisting of posts, mesh, grooves, irregularly shaped protrusions, and baffles that disperse thermal energy from a coolant fluid to said front wall and said rear wall.
